(19) United States
(12) Patent Application Publication
(10) Pub. No.: US 2021/0079282 A1
(43) Pub. Date: Mar. 18, 2021

(54) POLYMER-DERIVED ELASTIC HEAT SPREADER FILMS

(71) Applicant: Nanotek Instruments, Inc., Dayton, OH (US)

(72) Inventors: Yi-jun Lin, Taoyuan City (TW); Bor Z. Jang, Centerville, OH (US)

(73) Assignee: Nanotek Instruments, Inc., Dayton, OH (US)

(21) Appl. No.: 16/574,634

(22) Filed: Sep. 18, 2019

(51) Int. Cl. C09K 5/14; C08J 5/18; C08J 5/00; H05K 7/20; F28F 21/02; F28F 21/06

(52) U.S. Cl. CPC C09K 5/14; C08J 5/18; C08J 5/005; H05K 7/2039; C08J 2361/10; F28F 21/06; C08J 2379/06; C08J 2379/08; F28F 21/02

(57) ABSTRACT

Provided is an elastic heat spreader film comprising: a) a graphitic film prepared from graphitization of a polymer film or pitch film, wherein the graphitic film has graphitic crystals parallel to one another and parallel to a film plane, having an inter-graphene spacing less than 0.34 nm, and wherein the graphitic film alone, after compression, has a thermal conductivity at least 600 W/mK, an electrical conductivity no less than 4,000 S/cm, and a physical density greater than 1.7 g/cm³; and b) an elastomer or rubber that permeates into the graphitic film from at least a surface of the film; wherein the elastomer or rubber is in an amount from 0.001% to 30% by weight based on the total heat spreader film weight. The elastic heat spreader film has a fully recoverable tensile elastic strain from 2% to 100% and an in-plane thermal conductivity from 100 W/mK to 1,750 W/mK.

### FIELD

The present disclosure relates generally to the field of thermal films or heat spreaders and, more particularly, to a polymer-derived highly elastic heat spreader film and a process for producing same.

### BACKGROUND

Advanced thermal management materials are becoming more and more critical for today's microelectronic, photonic, and photovoltaic systems. As new and more powerful chip designs and light-emitting diode (LED) systems are introduced, they consume more power and generate more heat. This has made thermal management a crucial issue in today's high performance systems. Systems ranging from active electronically scanned radar arrays, web servers, large battery packs for personal consumer electronics, wide-screen displays, and solid-state lighting devices all require high thermal conductivity materials that can dissipate heat more efficiently. Furthermore, many microelectronic devices (e.g. smart phones, flat-screen TVs, tablets, and laptop computers) are designed and fabricated to become increasingly smaller, thinner, lighter, and tighter. This further increases the difficulty of thermal dissipation. Actually, thermal management challenges are now widely recognized as the key barriers to industry's ability to provide continued improvements in device and system performance.

Heat sinks are components that facilitate heat dissipation from the surface of a heat source, such as a CPU or battery in a computing device, to a cooler environment, such as ambient air. Typically, heat generated by a heat source must be transferred through a heat spreader to a heat sink or ambient air. A heat sink is designed to enhance the heat transfer efficiency between a heat source and the air mainly through increased heat sink surface area that is in direct contact with the air. This design enables a faster heat dissipation rate and thus lowers the device operating temperatures. In a microelectronic device, a high thermal conductivity of a heat spreader is essential to fast transfer of heat from a heat source to a heat sink or ambient air.

Current heat spreader films (or thermal films) are typically derived from polyimide films (via carbonization and graphitization of polyimide films, PI) or graphene sheets. Heat-spreading application of graphene-based films was first developed by our research group as early as 2007: Bor Z. Jang, et al. “Nano-scaled Graphene Plate Films and Articles,” U.S. patent application Ser. No. 11/784,606 (Apr. 9, 2007); now U.S. Pat. No. 9,233,850 (Jan. 12, 2016). Foldable handheld devices (e.g. foldable or bendable smart phones) are getting more and more popular. A foldable smart phone may be folded and unfolded more than 10,000 times during the useful life of this phone. Individual components, such as heat spreaders, in these devices are required to be foldable as well. However, both PI-derived and graphene-based thermal films (or any type of thermal films) have not been known to be capable of withstanding repeated bending deformations without significantly degrading desirable properties such as thermal conductivity and structural integrity.

The present disclosure was made to overcome the limitations of prior art heat spreader films outlined above.

### SUMMARY

In certain embodiments, the present disclosure provides an elastic heat spreader film comprising: (A) a graphitic film prepared from graphitization of a polymer film or pitch film, wherein the graphitic film has graphitic crystals substantially parallel to one another and parallel to a film plane, having an inter-graphene spacing less than 0.34 nm in the graphitic crystals, and wherein the graphitic film has a thermal conductivity of at least 600 W/mK (more typically and desirably greater than 1,000 W/mK), an electrical conductivity no less than 4,000 S/cm (typically greater than 6,000 S/cm), and a physical density greater than 1.5 g/cm³, all measured without the presence of a resin (i.e. without any rubber or elastomer); and (B) an elastomer or rubber that permeates into the graphitic film from at least a surface of the graphitic film; wherein the elastomer or rubber is in an amount from 0.001% to 20% by weight based on the total heat spreader film weight; wherein the elastic heat spreader film has a fully recoverable tensile elastic strain from 2% to 100% and an in-plane thermal conductivity from 100 W/mK to 1,750 W/mK (more typically greater than 200 W/mK, even more typically greater than 500 W/mK, further more typically greater than 800 W/mK, still more typically greater than 1000 W/mK, and most typically greater than 1250 W/mK).

Preferably, the polymer or pitch film is carbonized prior to graphitized. Typically, the graphitic crystals in graphitic films obtained via carbonization and graphitization (or direct graphitization without carbonization) of polymer or pitch films have a length/width less than 100 nm, more typically less than 60 nm, and further more typically less than 30 nm, and often less than 10 nm. The graphitic films typically have a width from 1 cm to 150 cm and a length from 1 cm to 1000 m (can be longer, depending upon the length of the starting polymer film, typically in a roll form).

Typically, the elastic heat spreader film has a fully recoverable tensile elastic strain from 5% to 50% and further more typically from 10% to 30%. The heat spreader film typically has a thickness from 10 nm to 500 μm.

Preferably, the elastomer or rubber impregnated into the graphitic film contains a material selected from natural polyisoprene, synthetic polyisoprene, polybutadiene, chloroprene rubber, polychloroprene, butyl rubber, styrene-butadiene rubber, nitrile rubber, ethylene propylene rubber, ethylene propylene diene rubber, metallocene-based poly(ethylene-co-octene) elastomer, poly(ethylene-co-butene) elastomer, styrene-ethylene-butadiene-styrene elastomer, epichlorohydrin rubber, polyacrylic rubber, silicone rubber, fluorosilicone rubber, perfluoro-elastomers, polyether block amides, chlorosulfonated polyethylene, ethylene-vinyl acetate, thermoplastic elastomer, protein resilin, protein elastin, ethylene oxide-epichlorohydrin copolymer, polyurethane, urethane-urea copolymer, a sulfonated version thereof, or a combination thereof.

The elastomer or rubber must have a high elasticity—a high tensile elastic deformation value (2%-1,000%) that is fully recoverable. It is well-known in the art of materials science and engineering that, by definition, an “elastic deformation” is a deformation that is fully recoverable upon release of the mechanical load, and the recovery process is essentially instantaneous (no significant time delay). An elastomer, such as a vulcanized natural rubber, can exhibit a tensile elastic deformation from 2% up to 1,000% (10 times of its original length), more typically from 10% to 800%, and further more typically from 50% to 500%, and most typically and desirably from 100% to 300%. If you use two hands to stretch a rubber band from 5 cm to, say, 40 cm and then release the rubber band from one hand, the rubber band immediately snaps back to substantially the original length. Such a deformation (800% in this example) is fully recoverable and there is substantially no plastic deformation (no permanent deformation). No materials other than elastomers or rubbers exhibit such a high-elasticity behavior.

For instance, although a metal typically has a high tensile ductility (i.e. can be extended to a large extent without breakage; e.g. from 10% to 200%), the majority of the deformation is plastic deformation (non-recoverable) and only a small amount of deformation is elastic deformation (i.e. the recoverable deformation being typically <1% and more typically <0.2%). Similarly, a non-elastomer polymer or plastic (thermoplastic or thermoset resin) may be able to stretch to a large extent, but most of the deformation is plastic deformation, a permanent deformation that is not recoverable upon release of the stress/strain. For instance, polyethylene (PE) may be able to get stretched to up to 200% under tensile load, but the majority (>98%) of such a deformation is non-recoverable, permanent deformation commonly referred to as the plastic deformation.

In some embodiments, the elastomer or rubber contains a material selected from natural polyisoprene (e.g. cis-1,4-polyisoprene natural rubber (NR) and trans-1,4-polyisoprene gutta-percha), synthetic polyisoprene (IR for isoprene rubber), polybutadiene (BR for butadiene rubber), chloroprene rubber (CR), polychloroprene (e.g. Neoprene, Baypren etc.), butyl rubber (copolymer of isobutylene and isoprene, IIR), including halogenated butyl rubbers (chloro butyl rubber (CIIR) and bromo butyl rubber (BIIR), styrene-butadiene rubber (copolymer of styrene and butadiene, SBR), nitrile rubber (copolymer of butadiene and acrylonitrile, NBR), EPM (ethylene propylene rubber, a copolymer of ethylene and propylene), EPDM rubber (ethylene propylene diene rubber, a terpolymer of ethylene, propylene and a diene-component), epichlorohydrin rubber (ECO), polyacrylic rubber (ACM, ABR), silicone rubber (SI, Q, VMQ), fluorosilicone rubber (FVMQ), fluoroelastomers (FKM, and FEPM; such as Viton, Tecnoflon, Fluorel, Aflas and Dai-El), perfluoroelastomers (FFKM: Tecnoflon PFR, Kalrez, Chemraz, Perlast), polyether block amides (PEBA), chlorosulfonated polyethylene (CSM; e.g. Hypalon), and ethylene-vinyl acetate (EVA), thermoplastic elastomers (TPE), protein resilin, protein elastin, ethylene oxide-epichlorohydrin copolymer, polyurethane, urethane-urea copolymer, and combinations thereof.

The resulting heat spreader film containing a properly selected elastomer or rubber as a binder or matrix material to hold the aligned graphitic crystals together is surprisingly capable of being stretched to a tensile elastic deformation >2%, more typically >5%, further more typically >10%, still more typically >20%, and often >50% (e.g. up to 100%).

It may be noted that such a high elasticity characteristic enables the heat spreader film to be bent or fold back and forth tens of thousands of times without significantly degrading the thermal conductivity. The thermal conductivity, typically from 500 to 1,750 W/mk before the first bending, can maintain >80% (typically >90%) of the original thermal conductivity after repeated bending by 10,000 times.

Preferably, in the above-cited embodiments, the elastomer or rubber is in an amount from 0.001% to 20% by weight, more preferably from 0.01% to 10% and further more preferably from 0.1% to 5%.

In some highly useful embodiments, the heat spreader film is in a thin film form having a thickness from 10 nm to 500 μm and the graphitic crystals are substantially aligned parallel to a thin film plane. Substantially aligned parallel graphitic material has graphitic crystals that deviate from parallel by 10 degrees or less, preferably 5 degrees or less. In some preferred embodiments, the heat spreader is in a thin film form having a thickness from 100 nm to 100 μm.

Typically, the disclosed heat spreader film has a tensile strength no less than 80 MPa, a tensile modulus no less than 20 GPa, a thermal conductivity no less than 500 W/mK, and/or an electrical conductivity no less than 5,000 S/cm, all measured along a thin film plane direction. Typically and preferably, the elastic heat spreader film has a tensile strength no less than 150 MPa, a tensile modulus no less than 30 GPa, a thermal conductivity no less than 800 W/mK, and/or an electrical conductivity no less than 8,000 S/cm, all measured along a thin film plane direction. In many cases, the elastic heat spreader film has a tensile strength no less than 200 MPa, a tensile modulus no less than 60 GPa, a thermal conductivity no less than 1,200 W/mK, and/or an electrical conductivity no less than 12,000 S/cm, all measured along a thin film plane direction. Some of the disclosed heat spreader films exhibit a tensile strength no less than 300 MPa, a tensile modulus no less than 120 GPa, a thermal conductivity no less than 1,500 W/mK, and/or an electrical conductivity no less than 20,000 S/cm, all measured along a thin film plane direction.

In some embodiments, the elastic heat spreader film has a thickness t, a front surface, and a back surface, wherein the elastomer/rubber is impregnated from at least one primary surface but preferably from two primary surfaces (front and back surfaces). The elastomer or rubber is able to penetrate from the front surface into a zone of the film by a distance ( 1/10) t and/or penetrate from the back surface into a zone at least by a distance ( 1/10) t and there is an elastomer-free core (i.e. the elastomer or rubber does not reach the central or core area of the film). The size of this elastomer-free core is typically from ( 1/10) t to ( 9/10) t.

In some embodiments, the graphitic film exhibits an inter-graphene spacing less than 0.337 nm and a mosaic spread value less than 1.0. In certain preferred embodiments, the graphitic film exhibits a degree of graphitization no less than 60% and/or a mosaic spread value less than 0.7. Most preferably, in the elastic heat spreader film, the graphitic film exhibits a degree of graphitization no less than 90% and/or a mosaic spread value less than 0.4.

The present disclosure also provides an electronic device containing the aforementioned heat spreader film as a component (e.g. as a thermal management element).

Additionally, the present disclosure provides a structural member containing the disclosed heat spreader film as a load-bearing and thermal management element.

The present disclosure also provides a process for producing the aforementioned elastic heat spreader film. In certain embodiments, the process comprises: (a) providing at least one film of polymer or pitch, having a film thickness from 10 nm to 1 mm; (b) subjecting the at least one film to a heat treatment at a graphitization temperature greater than 2000° C. (preferably >2300° C., further preferably >2500° C., and most preferably >2800° C.) in an non-oxidizing atmosphere to graphitize the film for obtaining a porous graphitized film, having a front surface and a back surface; (c) impregnating a rubber or elastomer resin from at least one of the front and back surfaces into the porous graphitized film to obtain a rubber/elastomer-impregnated film; and (d) compressing and consolidating the rubber/elastomer-impregnated film to produce the elastic heat spreader film.

In the disclosed process, the polymer film is preferably selected from the group consisting of polyimide, polyamide, phenolic resin, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, poly(pyromellitimide), poly(p-phenylene-isophthalamide), poly(m-phenylene-zoimidazole), poly(phenylene-benzobisimidazole), polyacrylonitrile, and combinations thereof.

In certain embodiments, the non-oxidizing atmosphere contains hydrogen gas, nitrogen gas, inert gas (e.g. He), or a combination thereof.

In certain embodiments, the pitch film is selected from a film of petroleum pitch, coal tar pitch, a polynuclear hydrocarbon, or a combination thereof. The polynuclear hydrocarbon may be selected from naphthalene, anthracene, phenanthrene, tetracene, chrysene, triphenylene, pyrene, pentacene, benzo-pyrene, corannulene, benzo-perylene, coronene, ovalene, benzo-fluorene, a derivative thereof having a substituent on a ring structure thereof, a chemical derivative thereof, or a combination thereof.

In some embodiments, the film of polymer or pitch further comprises from 0.01% to 50% by weight of multiple graphene sheets dispersed therein to form a graphene-enhanced polymer or pitch film, and wherein the graphene sheets are selected from pristine graphene, oxidized graphene, reduced graphene oxide, fluorinated graphene, hydrogenated graphene, doped graphene, chemically functionalized graphene, or a combination thereof.

In some embodiments, the film of polymer or pitch further comprises from 0.01% to 50% by weight of expanded graphite flakes or exfoliated graphite dispersed therein prior to the heat treatments. The polymer or pitch film may comprise a combination of expanded graphite flakes and graphene sheets dispersed therein prior to the heat treatment. The presence of graphene sheets appear to promote the graphitization process by decreasing the required graphitization temperature and accelerate the formation of graphitic crystals or graphite single crystals.

In certain embodiments, the process further comprises, prior to step (b), a procedure of carbonizing the film at a temperature selected from 300 to 2,500° C., and wherein the graphitization temperature is from 2,500° C. to 3,250° C.

In certain embodiments, the elastomer or rubber contains a material selected from natural polyisoprene, synthetic polyisoprene, polybutadiene, chloroprene rubber, polychloroprene, butyl rubber, styrene-butadiene rubber, nitrile rubber, ethylene propylene rubber, ethylene propylene diene rubber, metallocene-based poly(ethylene-co-octene) elastomer, poly(ethylene-co-butene) elastomer, styrene-ethylene-butadiene-styrene elastomer, epichlorohydrin rubber, polyacrylic rubber, silicone rubber, fluorosilicone rubber, perfluoro-elastomers, polyether block amides, chlorosulfonated polyethylene, ethylene-vinyl acetate, thermoplastic elastomer, protein resilin, protein elastin, ethylene oxide-epichlorohydrin copolymer, polyurethane, urethane-urea copolymer, a sulfonated version thereof, or a combination thereof.

In certain embodiments, the porous graphitized film has a physical density from 0.01 g/cm³ to 1.5 g/cm³ and, upon compressing and consolidating, the rubber/elastomer-impregnated film has a physical density from 1.5 g/cm³ to 2.25 g/cm³.

In certain embodiments, the graphitization temperature is from 2,500° C. to 3,250° C.

In certain embodiments, the process is a continuous process that includes continuously or intermittently feeding the polymer or pitch film into a carbonization zone containing a temperature from 300° C. to 2,500° C. and then into a graphitization zone containing a temperature from 2,500° C. to 3,250° C., followed by retreating the porous graphitized film from the graphitization zone.

Preferably, the polymer or pitch film is under a compression stress while being graphitized.

In certain embodiments, the polymer or pitch film is supported on a first refractory material plate and covered by a second refractory material plate to exert a compressive stress to said polymer or pitch film while being graphitized. The first refractory material or second refractory material may be selected from graphite, a refractory metal, or a carbide, oxide, boride, or nitride of a refractory element selected from tungsten, zirconium, tantalum, niobium, molybdenum, tantalum, or rhenium.

In certain embodiments, the polymer or pitch film has a thickness from 1 μm to 200 μm.

The process may further comprise implementing the elastic heat spreader film into a device as a thermal management element in this device.

### BRIEF DESCRIPTION OF THE DRAWINGS

FIG. 1 Schematic of the process for producing an elastic heat spreader film containing elastomer/rubber-impregnated graphitic film, according to certain embodiments of the disclosure.

FIG. 2 Chemical reactions associated with production of PBO.

FIG. 3(A) Thermal conductivity values, plotted as a function of the number of repeated bending deformations, of polymer-derived graphitic films with and without elastomer impregnation;

FIG. 3(B) Thermal conductivity values, plotted as a function of the number of repeated bending deformations, of graphene-reinforced polymer-derived graphitic films with and without elastomer impregnation;

FIG. 3(C) Thermal conductivity values, plotted as a function of the number of repeated bending deformations, of expanded graphite flake-reinforced polymer-derived graphitic films with and without elastomer impregnation;

FIG. 3(D) Schematic drawing that illustrates the repeated bending test.

FIG. 4 Thermal conductivity values over weight percentage of elastomer for two series of heat spreader films: one series containing graphitic films derived from graphene-reinforced PI films and the other series containing graphitic films derived from PI films; both containing elastomer resin permeated from two sides of the graphitic film.

FIG. 5 Electrical conductivity values, plotted as a function of the number of repeated bending deformations, of graphene-reinforced PBI-derived graphitic films with and without elastomer impregnation.

### DESCRIPTION OF THE PREFERRED EMBODIMENTS

The present disclosure provides an elastic heat spreader film comprising: (A) a graphitic film prepared from graphitization of a polymer film or pitch film, wherein the graphitic film has graphitic crystals substantially parallel to one another and parallel to a film plane and the graphitic crystals have an inter-graphene spacing less than 0.34 nm, and wherein the graphitic film has a thermal conductivity of at least 600 W/mK (typically >1,000 W/mK), an electrical conductivity no less than 4,000 S/cm (typically >6,000 S/cm), and a physical density greater than 1.5 g/cm³ (typically from 1.6 g/cm³ to 2.26 g/cm³), all measured without the presence of a resin (i.e. without any rubber or elastomer); and (B) an elastomer or rubber that permeates into the graphitic film from at least a surface of the graphitic film; wherein the elastomer or rubber is in an amount from 0.001% to 20% by weight based on the total heat spreader film weight; wherein the elastic heat spreader film has a fully recoverable tensile elastic strain from 2% to 100% and an in-plane thermal conductivity from 100 W/mK to 1,750 W/mK (more typically greater than 200 W/mK, even more typically greater than 500 W/mK, further more typically greater than 800 W/mK, still more typically greater than 1000 W/mK, and most typically greater than 1250 W/mK).

Typically, the graphitic crystals in the graphitic films obtained via carbonization and graphitization of polymer films have a length or width less than 100 nm, more typically less than 60 nm, and further more typically less than 30 nm, and often less than 10 nm. The graphitic films typically have a width from 1 cm to 150 cm and a length from 1 cm to 1000 m (can be longer, depending upon the length of the starting polymer film, typically in a roll form).

The elastomer or rubber material must have a high elasticity (high elastic deformation value). An elastic deformation is a deformation that is fully recoverable and the recovery process is essentially instantaneous (no significant time delay). An elastomer, such as a vulcanized natural rubber, can exhibit an elastic deformation from 2% up to 1,000% (10 times of its original length), more typically from 10% to 800%, and further more typically from 50% to 500%, and most typically and desirably from 100% to 500%. It may be noted that although a metal or a plastic material typically has a high ductility (i.e. can be extended to a large extent without breakage), the majority of the deformation is plastic deformation (i.e. non-recoverable, permanent deformation) and only a small amount (typically <1% and more typically <0.2%) is elastic deformation.

The elastomeric material may be selected from natural polyisoprene (e.g. cis-1,4-polyisoprene natural rubber (NR) and trans-1,4-polyisoprene gutta-percha), synthetic polyisoprene (IR for isoprene rubber), polybutadiene (BR for butadiene rubber), chloroprene rubber (CR), polychloroprene (e.g. Neoprene, Baypren etc.), butyl rubber (copolymer of isobutylene and isoprene, UR), including halogenated butyl rubbers (chloro butyl rubber (CIIR) and bromo butyl rubber (BIIR), styrene-butadiene rubber (copolymer of styrene and butadiene, SBR), nitrile rubber (copolymer of butadiene and acrylonitrile, NBR), EPM (ethylene propylene rubber, a copolymer of ethylene and propylene), EPDM rubber (ethylene propylene diene rubber, a terpolymer of ethylene, propylene and a diene-component), epichlorohydrin rubber (ECO), polyacrylic rubber (ACM, ABR), silicone rubber (SI, Q, VMQ), fluorosilicone rubber (FVMQ), fluoroelastomers (FKM, and FEPM; such as Viton, Tecnoflon, Fluorel, Aflas and Dai-El), perfluoroelastomers (FFKM: Tecnoflon PFR, Kalrez, Chemraz, Perlast), polyether block amides (PEBA), chlorosulfonated polyethylene (CSM; e.g. Hypalon), and ethylene-vinyl acetate (EVA), thermoplastic elastomers (TPE), protein resilin, protein elastin, ethylene oxide-epichlorohydrin copolymer, polyurethane, urethane-urea copolymer, and combinations thereof.

The urethane-urea copolymer film usually consists of two types of domains, soft domains and hard ones. Entangled linear backbone chains consisting of poly(tetramethylene ether) glycol (PTMEG) units constitute the soft domains, while repeated methylene diphenyl diisocyanate (MDI) and ethylene diamine (EDA) units constitute the hard domains. Actually, most of the thermoplastic elastomers have hard domains and soft domains in their structure, or hard domains dispersed in a soft matrix. The hard domains can help hold the lightly cross-linked or physically entangled chains together, enabling deformation reversibility of the chains.

The resulting heat spreader film containing a properly selected elastomer or rubber as a binder or matrix material to hold the aligned graphitic crystals together is surprisingly capable of being stretched to a tensile elastic deformation >2%, more typically >5%, further more typically >10%, still more typically >20%, and often >50% (e.g. up to 100%).

It may be noted that such a high elasticity characteristic enables the heat spreader film to be bent or fold back and forth tens of thousands of times without significantly degrading the thermal conductivity. The thermal conductivity, typically from 500 to 1,750 W/mk before the first bending, can maintain >80% (typically >90%) of the original thermal conductivity after repeated bending by 10000 times.

Preferably, in the above-cited embodiments, the elastomer or rubber is in an amount from 0.001% to 20% by weight, more preferably from 0.01% to 10% and further more preferably from 0.1% to 1%.

Typically, the disclosed heat spreader film has a tensile strength no less than 80 MPa, a tensile modulus no less than 20 GPa, a thermal conductivity no less than 500 W/mK, and/or an electrical conductivity no less than 5,000 S/cm, all measured along a thin film plane direction. Typically and preferably, the elastic heat spreader film has a tensile strength no less than 150 MPa, a tensile modulus no less than 30 GPa, a thermal conductivity no less than 800 W/mK, and/or an electrical conductivity no less than 8,000 S/cm, all measured along a thin film plane direction. In many cases, the elastic heat spreader film has a tensile strength no less than 200 MPa, a tensile modulus no less than 60 GPa, a thermal conductivity no less than 1,200 W/mK, and/or an electrical conductivity no less than 12,000 S/cm, all measured along a thin film plane direction. Some of the disclosed heat spreader films exhibit a tensile strength no less than 300 MPa, a tensile modulus no less than 120 GPa, a thermal conductivity no less than 1,500 W/mK, and/or an electrical conductivity no less than 20,000 S/cm, all measured along a thin film plane direction.

In some embodiments, the elastic heat spreader film has a thickness t, a front surface, and a back surface, wherein the elastomer/rubber is impregnated from at least one primary surface but preferably from two primary surfaces (front and back surfaces). The elastomer or rubber is able to penetrate from the front surface into a zone of the film by a distance ( 1/10) t and/or penetrate from the back surface into a zone at least by a distance ( 1/10) t and there is an elastomer-free core (i.e. the elastomer or rubber does not reach the central or core area of the film). The size of this elastomer-free core is typically from ( 1/10) t to ( 9/10) t.

In some embodiments, the graphitic film exhibits an inter-graphene spacing less than 0.337 nm and a mosaic spread value less than 1.0. In certain preferred embodiments, the graphitic film exhibits a degree of graphitization no less than 60% and/or a mosaic spread value less than 0.7. Most preferably, in the elastic heat spreader film, the graphitic film exhibits a degree of graphitization no less than 90% and/or a mosaic spread value less than 0.4.

The present disclosure also provides an electronic device containing the aforementioned heat spreader film as a component (e.g. as a thermal management element).

Additionally, the present disclosure provides a structural member containing the disclosed heat spreader film as a load-bearing and thermal management element.

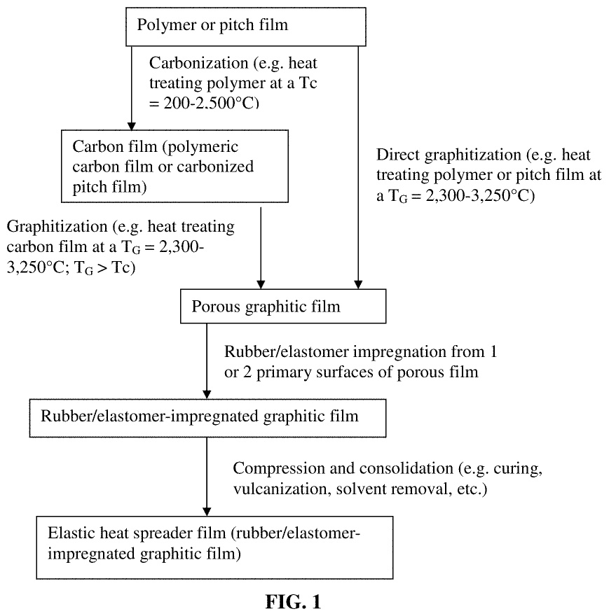

The present disclosure also provides a process for producing the aforementioned elastic heat spreader film. In certain embodiments, as schematically illustrated in FIG. 1, the process comprises: (a) providing at least one film of polymer or pitch, having a film thickness no less than 5 nm (preferably from 10 nm to 5 mm, and more preferably from 100 nm to 1 mm); (b) subjecting the at least one film to a heat treatment at a graphitization temperature greater than 2000° C. (preferably >2300° C., further preferably >2500° C., and most preferably >2800° C.) in an non-oxidizing atmosphere to graphitize the film for obtaining a porous graphitized film, having a front surface and a back surface; (c) impregnating a rubber or elastomer resin from at least one of the front and back surfaces into the porous graphitized film to obtain a rubber/elastomer-impregnated film; and (d) compressing and consolidating the rubber/elastomer-impregnated film to produce the elastic heat spreader film. Graphitization leads to the formation of graphitic crystals inside the film.

The graphitization treatment may be preceded by a carbonization treatment of the polymer or pitch film, as illustrated in the left-hand side of FIG. 1. In other words, the polymer or pitch film is carbonized (e.g. at a carbonization temperature, Tc=200-2,500° C.) to obtain a polymeric carbon or carbonized pitch, which is then graphitized at a graphitization temperature, T_{G} (e.g. T_{G}=2,300-3,250° C.; T_{G}>Tc). The product of the heat treatment (carbonization and then graphitization or direct graphitization, bypassing the carbonization step) is a porous graphitic film, typically having surface and internal pores.

In the disclosed process, the polymer film is preferably selected from the group consisting of polyimide, polyamide, phenolic resin, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, poly(pyromellitimide), poly(p-phenylene-isophthalamide), poly(m-phenylene-zoimidazole), poly(phenylene-benzobisimidazole), polyacrylonitrile, and combinations thereof.

In certain embodiments, the non-oxidizing atmosphere contains hydrogen gas, nitrogen gas, an inert gas (e.g. He), or a combination thereof.

In certain embodiments, the pitch film is selected from a film of petroleum pitch, coal tar pitch, a polynuclear hydrocarbon, or a combination thereof. The polynuclear hydrocarbon may be selected from naphthalene, anthracene, phenanthrene, tetracene, chrysene, triphenylene, pyrene, pentacene, benzo-pyrene, corannulene, benzo-perylene, coronene, ovalene, benzo-fluorene, a derivative thereof having a substituent on a ring structure thereof, a chemical derivative thereof, or a combination thereof.

Preferably, the film of polymer or pitch further comprises from 0.01% to 50% by weight of multiple graphene sheets dispersed therein to form a graphene-enhanced polymer or pitch film, and wherein the graphene sheets are selected from pristine graphene, oxidized graphene, reduced graphene oxide, fluorinated graphene, hydrogenated graphene, doped graphene, chemically functionalized graphene, or a combination thereof. Graphene sheets may also be referred to as nano graphene platelets (NGPs).

In some embodiments, the film of polymer or pitch further comprises from 0.01% to 50% by weight of expanded graphite flakes or exfoliated graphite dispersed therein prior to the heat treatments.

The polymer or pitch film may comprise a combination of expanded graphite flakes and graphene sheets dispersed therein prior to the heat treatment. The presence of graphene sheets appear to promote the graphitization process by decreasing the required graphitization temperature and accelerate the formation of graphitic crystals or graphite single crystals.

In certain embodiments, the process further comprises, prior to step (b), a procedure of carbonizing the film at a temperature selected from 300 to 2,500° C., and wherein the graphitization temperature is from 2,500° C. to 3,250° C.

A precursor to the rubber/elastomer (e.g. liquid monomer/curing agent mixture, oligomers, or uncured resin dissolved in a solvent, etc.) may be impregnated or infiltrated, through one or two primary surfaces of the porous graphitic film, into the pores of the porous graphitic film after the heat treatment. After the rubber/elastomer impregnation, the resulting impregnated graphitic film may be subjected to compression (e.g. roll-pressing) to align/orient the graphitic crystals to become parallel to each other. Curing, cross-linking, vulcanization, and/or solvent removing may be conducted just before, during or after the compression step. The elastomer is impregnated to serve as a binder material or as a matrix material. The multiple graphitic crystals are bonded by the binder material or dispersed in the matrix material and the elastomer or rubber is in an amount from 0.001% to 30% by weight (more typically from 0.01% to 20%) based on the total heat spreader film weight, wherein the elastic heat spreader film has a fully recoverable tensile elastic strain from 2% to 100% and an in-plane thermal conductivity from 200 W/mK to 1,750 W/mK.

The following examples are used to illustrate some specific details about the best modes of practicing the instant disclosure and should not be construed as limiting the scope of the disclosure. The tensile properties, thermal conductivity, and electrical conductivity of the films were measured by following well-known standard procedures.

### Example 1: Preparation of Discrete Graphene Sheets and Expanded Graphite Flakes as a Reinforcement Additive for Polymer or Pitch Films Prior to Heat Treatments

Natural graphite powder with an average lateral dimension of 45 μm was used as a starting material, which was immersed in a mixture of concentrated sulfuric acid, nitric acid, and potassium permanganate (as the chemical intercalate and oxidizer) to prepare graphite intercalation compounds (GICs). The starting material was first dried in a vacuum oven for 24 h at 80° C. Then, a mixture of concentrated sulfuric acid, fuming nitric acid, and potassium permanganate (at a weight ratio of 4:1:0.05) was slowly added, under appropriate cooling and stirring, to a three-neck flask containing fiber segments. After 16 hours of reaction, the acid-treated natural graphite particles were filtered and washed thoroughly with deionized water until the pH level of the solution reached 4.0. After being dried at 100° C. overnight, the resulting graphite intercalation compound (GIC) was subjected to a thermal shock at 1050° C. for 45 seconds in a tube furnace to form exfoliated graphite (EG or graphite worms).

Five grams of the resulting exfoliated graphite (graphite worms) were mixed with 2,000 ml alcohol solution consisting of alcohol and distilled water with a ratio of 65:35 for 2 hours to obtain a suspension. Then the mixture or suspension was subjected to ultrasonic irradiation with a power of 200 W for various times. After two intermittent sonication treatments each of 1.5 hours, EG particles were effectively fragmented into thin graphene sheets. The suspension was then filtered and dried at 80° C. to remove residue solvents. The as-prepared graphene sheets (thermally reduced GO) have an average thickness of approximately 3.4 nm.

Another five grams of the resulting exfoliated graphite worms were subjected to low-intensity air jet milling to break up graphite worms, forming expanded graphite flakes (having an average thickness of 139 nm). Graphite worms, expanded graphite flakes, and graphene sheets, separately or in combinations, may be used as a reinforcement additive in polymer or pitch films prior to heat treatments.

### Example 2: Preparation of Single-Layer Graphene Sheets from Meso-Carbon Micro-Beads (MCMBs) as a Reinforcement Additive for Polymer or Pitch Films Prior to Heat Treatments

Meso-carbon microbeads (MCMBs) were supplied from China Steel Chemical Co. This material has a density of about 2.24 g/cm³ with a median particle size of about 16 μm. MCMB (10 grams) were intercalated with an acid solution (sulfuric acid, nitric acid, and potassium permanganate at a ratio of 4:1:0.05) for 72 hours. Upon completion of the reaction, the mixture was poured into deionized water and filtered. The intercalated MCMBs were repeatedly washed in a 5% solution of HCl to remove most of the sulfate ions. The sample was then washed repeatedly with deionized water until the pH of the filtrate was neutral. The slurry was dried and stored in a vacuum oven at 60° C. for 24 hours. The dried powder sample was placed in a quartz tube and inserted into a horizontal tube furnace pre-set at a desired temperature, 1,080° C. for 45 seconds to obtain a graphene material. TEM and atomic force microscopic studies indicate that most of the graphene sheets were single-layer graphene.

### Example 3: Preparation of Pristine Graphene Sheets as a Reinforcement Additive for Polymer or Pitch Films Prior to Heat Treatments

In a typical procedure, five grams of graphite flakes, ground to approximately 20 μm or less in sizes, were dispersed in 1,000 mL of deionized water (containing 0.1% by weight of a dispersing agent, Zonyl® FSO from DuPont) to obtain a suspension. An ultrasonic energy level of 85 W (Branson S450 Ultrasonicator) was used for exfoliation, separation, and size reduction of graphene sheets for a period of 15 minutes to 2 hours. The suspension was spray-dried to produce pristine graphene sheets for use as a reinforcement for the polymer or pitch film.

### Example 4: Preparation of Graphene Fluoride as a Reinforcement Additive for Polymer or Pitch Films Prior to Heat Treatments

Several processes have been used by us to produce GF, but only one process is herein described as an example. In a typical procedure, highly exfoliated graphite (HEG) was prepared from intercalated compound C₂F.xClF₃. HEG was further fluorinated by vapors of chlorine trifluoride to yield fluorinated highly exfoliated graphite (FHEG). A pre-cooled Teflon reactor was filled with 20-30 mL of liquid pre-cooled ClF₃, and then the reactor was closed and cooled to liquid nitrogen temperature. Subsequently, no more than 1 g of HEG was put in a container with holes for ClF₃ gas to access the reactor. After 7-10 days, a gray-beige product of GF sheets with approximate formula C₂F was formed.

### Example 5: Preparation of Nitrogenated Graphene as a Reinforcement Additive for Polymer or Pitch Films Prior to Heat Treatments

Graphene oxide (GO), synthesized in Example 2, was finely ground with different proportions of urea and the pelletized mixture heated in a microwave reactor (900 W) for 30 s. The product was washed several times with deionized water and vacuum dried. In this method graphene oxide gets simultaneously reduced and doped with nitrogen. The products obtained with graphene/urea mass ratios of 1/0.5, 1/1 and 1/2 are designated as N-1, N-2 and N-3 respectively and the nitrogen contents of these samples were 14.7, 18.2 and 17.5 wt. % respectively as determined by elemental analysis.

### Example 6: Functionalized Graphene-Based Thermal Films as a Reinforcement Additive for Polymer or Pitch Films Prior to Heat Treatments

Thermal films were prepared from elastomer impregnation of graphitic films; the latter were prepared from carbonization and graphitization of functionalized graphene-reinforced polymer films. Chemical functional groups involved in this study include an azide compound (2-Azidoethanol), alkyl silane, hydroxyl group, carboxyl group, amine group, sulfonate group (—SO₃H), and diethylenetriamine (DETA). These functionalized graphene sheets were supplied from Taiwan Graphene Co., Taipei, Taiwan.

### Example 7: Preparation of Elastomer-Impregnated Graphitic Films from Polybenzoxazole (PBO) Films, PBO/Graphene Films, and PBO/Expanded Graphite Flake Films

Polybenzoxazole (PBO) films were prepared via casting and thermal conversion from its precursor, methoxy-containing polyaramide (MeO-PA). Specifically, monomers of 4,4′-diamino-3,3′-dimethoxydiphenyl (DMOBPA), and isophthaloyl dichloride (IPC) were selected to synthesize PBO precursors, methoxy-containing polyaramide (MeO-PA) solution. This MeO-PA solution for casting was prepared by polycondensation of DMOBPA and IPC in DMAc solution in the presence of pyridine and LiCl at −5° C. for 2 hr, yielding a 20 wt % pale yellow transparent MeO-PA solution. The inherent viscosity of the resultant MeO-PA solution was 1.20 dL/g measured at a concentration of 0.50 g/dl at 25° C. This MeO-PA solution was diluted to a concentration of 15 wt % by DMAc for casting.

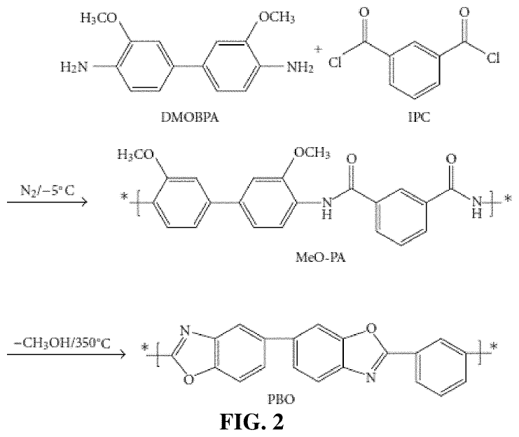

The as-synthesized MeO-PA was cast onto a glass surface to form thin films (35-120 μm) under a shearing condition. The cast film was dried in a vacuum oven at 100° C. for 4 hr to remove the residual solvent. Then, the resulting film with thickness of approximately 28-100 μm was treated at 200° C.-350° C. under N₂ atmosphere in three steps and annealed for about 2 hr at each step. This heat treatment serves to thermally convert MeO-PA into PBO films. The chemical reactions involved may be illustrated in FIG. 2. For comparison, both graphene-reinforced PBO (NGP-PBO) and expanded graphite flake-PBO films were made under similar conditions. The NGP or EP flake proportions, prepared in Example 1, were varied from 0.01% to 50% by weight.

All the films prepared were pressed between two plates of alumina while being heat-treated (carbonized) under a 3-sccm argon gas flow in three steps: from room temperature to 600° C. in 1 h, from 600 to 1,000° C. in 1.5 h, and maintained at 1,000° C. for 1 h. The carbonized films were then roll-pressed in a pair of rollers to reduce the thickness by approximately 40%. The roll-pressed films were then subjected to graphitization treatments at 2,500° C. for 2 hours to produce porous graphitic films.

Subsequently, some of the porous graphitic films were impregnated from both primary surfaces of the porous graphitic film with a urethane oligomer (a mixture of di-isocyanate and polyol) dissolved in acetone. Upon impregnation, the liquid medium (acetone) was removed from the impregnated film, which was compressed with a heated press and cured at 150° C. for 45 minutes.

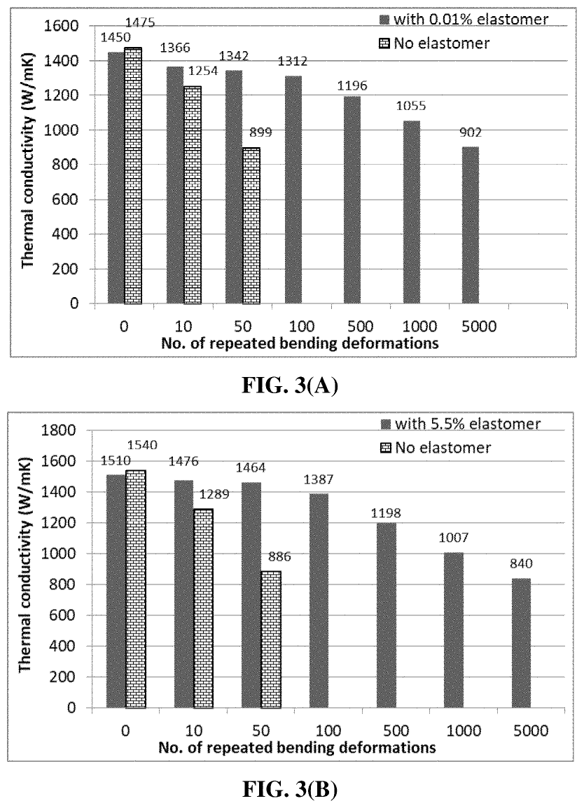

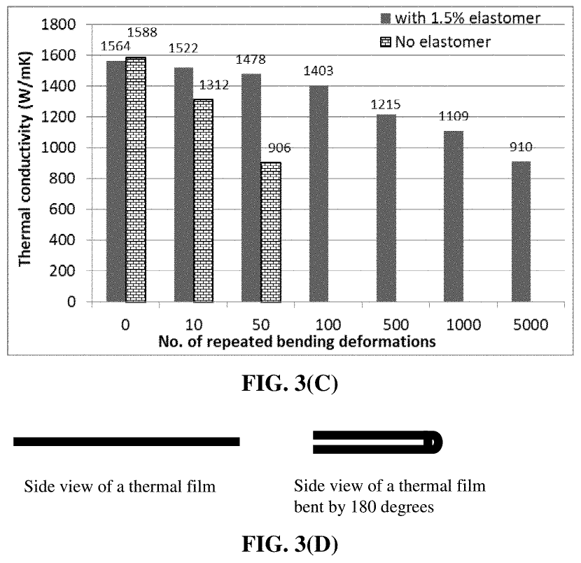

FIG. 3(A) shows the thermal conductivity values, plotted as a function of the number of repeated bending deformations, of two series of heat spreader films: one series containing polymer-derived porous graphitic films that are impregnated with 0.1% by weight of elastomer and then compressed, and the other series containing polymer-derived porous graphitic films that are compressed without elastomer impregnation.

As one can see, the samples containing no elastomer exhibit a drop in thermal conductivity from 1,475 W/mK to 899 W/mk after 50 bending deformations, each by 180 degrees. The sheet was broken after 65 cycles of bending. In contrast, a small amount of elastomer incorporated into the heat spreader films can help the graphitic film withstand 5,000 times of repeated bending without breaking and still maintains a relatively high thermal conductivity.

Bending test is easy to perform, as illustrated in FIG. 3(D). One can take a desired number of identical thermal films and measure thermal conductivity of a specimen prepared by slitting a piece of the film across the bending area, after a desired number of repeated bending deformations, and then measure the thermal conductivity of this piece using the well-known Laser Flash or other method.

Generally speaking, an increase in the elastomer proportion in the graphitic films leads to a reduction in the thermal conductivity of the graphitic films. These thermal films have their elastomer resin impregnated inward from the two primary surfaces of a film; impregnation occurs after the graphitic film is made. This process typically leads to a heat spreader structure having an elastomer-free core; the elastomer permeates only a limited distance from the two primary surfaces of a porous graphitic film, not reaching the center. One can also find a way to allow for complete permeation of the graphitic film by an elastomer resin; e.g. by forming a porous film first, followed by impregnation for an extended period of time, followed by full compaction. An elastic heat spreader film has a thickness t, and two primary surfaces (referred to as a front surface and a back surface). In the examples investigated, typically the elastomer or rubber is able to penetrate to a zone away from the front surface at least by a distance 1/10 t and/or to a zone away from the back surface at least by a distance 1/10 t deep into the film. One can produce a heat spreader film having an elastomer-free core size from 1/10 t to 9/10 t.

FIG. 3(B) shows the thermal conductivity values, plotted as a function of the number of repeated bending deformations, of graphene-reinforced polymer-derived graphitic films with and without elastomer impregnation. The incorporation of graphene sheets appears to increase the thermal conductivity of graphitic films. Again, the thermal films without elastomer impregnation are not capable of withstanding repeated deformations for more than 70 times.

FIG. 3(C) shows the thermal conductivity values, plotted as a function of the number of repeated bending deformations, of expanded graphite-reinforced polymer-derived graphitic films with and without elastomer impregnation. The incorporation of expanded graphite flakes appears to increase the thermal conductivity of graphitic films. The thermal films without elastomer impregnation are not capable of withstanding repeated deformations for more than 70 times.

### Example 8: Preparation of Graphitic Films from Polyimide (PI) Films and Graphene-Reinforced PI Films

The synthesis of conventional polyimide (PI) involved poly(amic acid) (PAA, Sigma Aldrich) formed from pyromellitic dianhydride (PMDA) and oxydianiline (ODA). Prior to use, both chemicals were dried in a vacuum oven at room temperature. Next, as an example, 4 g of the monomer ODA was dissolved into 21 g of DMF solution (99.8 wt %). This solution was stored at 5° C. before use. PMDA (4.4 g) was added, and the mixture was stirred for 30 min using a magnetic bar. Subsequently, the clear and viscous polymer solution was separated into four samples. Triethyl amine catalyst (TEA, Sigma Aldrich) with 0, 1, 3, and 5 wt % was then added into each sample to control the molecular weight. Stirring was maintained by a mechanical stirrer until the entire quantity of TEA was added. The as-synthesized PAA was kept at −5° C. to maintain properties essential for further processing.

Solvents utilized in the poly(amic acid) synthesis play a very important role. Common dipolar aprotic amide solvents utilized are DMF, DMAc, NMP and TMU. DMAc was utilized in the present study. The intermediate poly(amic acid) and graphene/PAA precursor composite were converted to the final polyimide by the thermal imidization route. Graphene sheets used were prepared in Examples 2 and 3. Films were first cast on a glass substrate and then allowed to proceed through a thermal cycle with temperatures ranging from 100° C. to 350° C. The procedure entails heating the poly(amic acid) mixture to 100° C. and holding for one hour, heating from 100° C. to 200° C. and holding for one hour, heating from 200° C. to 300° C. and holding for one hour and slow cooling to room temperature from 300° C.

The PI and graphene-reinforced PI films, pressed between two alumina plates, were heat-treated under a 3-sccm argon gas flow at 1,000° C. This occurred in three steps: from room temperature to 600° C. in 1 h, from 600 to 1,000° C. in 1.3 h, and 1,000° C. maintained for 1 h. The carbonized films were then graphitized at a temperature of 2,780° C. for 1 hour to obtain porous graphitic films. After heat treatments, the films were sprayed with some rubber solution (e.g. polyisoprene in THF), which was then dried to remove the solvent. The rubber-impregnated films were then roll-pressed with the rubber cured.

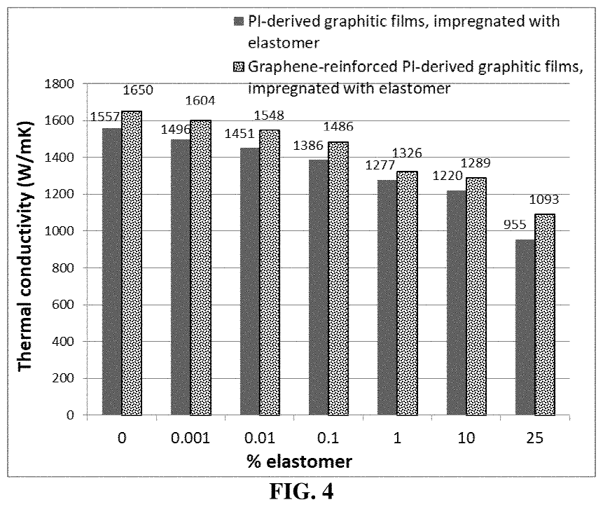

The thermal conductivity values of two series of graphitic films derived from PI and graphene/PI films (30% graphene+70% PI), after impregnation with a range of rubber proportions and then compression, are summarized in FIG. 4. The chart indicates that the thermal conductivity of the graphitic films decreases with increasing rubber content.

### Example 9: Preparation of Graphitic Films Derived from Phenolic Resin Films, Expanded Graphite/Phenolic Resin Films, and Graphene/Phenolic Films

Phenol formaldehyde resins (PF) are synthetic polymers obtained by the reaction of phenol or substituted phenol with formaldehyde. The PF resin, alone or with 25% by weight graphene fluoride sheets (prepared in Example 4) or expanded graphite (EP) flakes (prepared in Example 1), was made into 50-μm thick films and cured under identical curing conditions: a steady isothermal cure temperature at 100° C. for 2 hours and then increased from 100 to 170° C. and maintained at 170° C. to complete the curing reaction.

All the thin films were then carbonized at 500° C. for 2 hours and then at 700° C. for 3 hours. The carbonized films were then subjected to further heat treatments (graphitization) at temperatures that were varied from 2,500 to 2,950° C. for 2 hours.

After heat treatments, the porous graphitic films were sprayed with some rubber solution (e.g. ethylene oxide-epichlorohydrin copolymer dissolved in xylene), which was then dried to remove the solvent. The rubber-impregnated films were then roll-pressed with the rubber cured. Some porous graphitic films, without rubber impregnation, were also roll-pressed to obtain consolidated graphitic films for comparison purposes. Again, we have observed that graphitic films without rubber/elastomer impregnation generally cannot withstand repeated bending deformations for more than 100 times. In contrast, rubber-impregnated graphitic films can last for 3,000-12,000 times.

### Example 10: Preparation of Graphitic Films from Polybenzimidazole (PBI) Films and Graphene/PBI Films

PBI is prepared by step-growth polymerization from 3,3′,4,4′-tetraaminobiphenyl and diphenyl isophthalate (an ester of isophthalic acid and phenol). The PBI used in the present study was obtained from PBI Performance Products in a PBI solution form, which contains 0.7 dl/g PBI polymer dissolved in dimethylacetamide (DMAc). The PBI and NGP-PBI films were cast onto the surface of a glass substrate. The heat treatment, elastomer resin impregnation, and roll-pressing procedures were similar to those used in Example 7 for PBO.

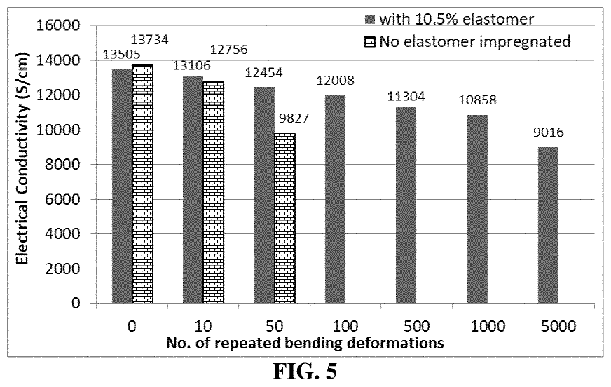

Shown in FIG. 5 are electrical conductivity values, plotted as a function of the number of repeated bending deformations, of graphene-reinforced PBI-derived graphitic films with and without elastomer impregnation. It is clear that the approach of elastomer impregnation can impart dramatic resistance of graphitic films against repeated bending deformations.

### Example 11: Graphitic Films from Various Pitch-Based Carbon Precursors

Additional elastomer-impregnated graphitic films were prepared from several different types of precursor materials. Their electric and thermal conductivity values are listed in Table 1 below.

TABLE 1
Preparation conditions and properties of graphitic films from other precursor materials

| | | | Graphitization | | Electric | Thermal |
|---|---|---|---|---|---|---|
| Sample | | Carbon | temperature | Elastomer/ | conduc. | conduc. |
| No. | NGP or EP | Precursor | (° C.) | rubber | (S/cm) | (W/mK) |
| 12-A | Pristine | Petroleum | 2,850 | Urea-urethane | 12,300 | 1485 |
| | graphene, 25% | pitch | | copolymer | | |
| 12-B | None | Petroleum | 2,850 | Urea-urethane | 11,850 | 1444 |
| | | pitch | | copolymer | | |
| 12-C | EP, 30% | Petroleum | 2,850 | Urea-urethane | 11,976 | 1466 |
| | | pitch | | copolymer | | |
| 15-A | Reduced GO, | Naphthalene | 2,800 | Polyurethane | 13,322 | 1555 |
| | 35% | | | | | |
| 16-A | Fluorinated | Coal tar | 2,750 | Polyisoprene | 12,022 | 1466 |
| | graphene, 50% | pitch | | | | |
| 16-B | none | Coal tar | 2,750 | SBR | 13,255 | 1550 |
| | | pitch | | | | |

### Example 12: Characterization of Graphitic Films

X-ray diffraction curves of a carbonized or graphitized material were monitored as a function of the heat treatment temperature and time. The peak at approximately 2θ=22-23° of an X-ray diffraction curve corresponds to an inter-graphene spacing (d₀₀₂) of approximately 0.3345 nm in natural graphite. With some heat treatment at a temperature >1,500° C. of a carbonized aromatic polymer, such as PI, PBI, and PBO, the material begins to see diffraction curves exhibiting a peak at 2θ<12° C. The angle 2θ shifts to higher values when the graphitization temperature and/or time are increased. With a heat treatment temperature of 2,500° C. for 1-5 hours, the d₀₀₂ spacing typically is decreased to approximately 0.336 nm, close to 0.3354 nm of a graphite single crystal.

With a heat treatment temperature of 2,750° C. for 5 hours, the d₀₀₂ spacing is decreased to approximately to 0.3354 nm, identical to that of a graphite single crystal. In addition, a second diffraction peak with a high intensity appears at 2θ=55° corresponding to X-ray diffraction from (004) plane. The (004) peak intensity relative to the (002) intensity on the same diffraction curve, or the I(004)/I(002) ratio, is a good indication of the degree of crystal perfection and preferred orientation of graphene planes.

The (004) peak is either non-existing or relatively weak, with the I(004)/I(002) ratio <0.1, for all graphitic materials obtained from neat matrix polymers (containing no dispersed NGPs) heat treated at a final temperature lower than 2,800° C. For these materials, the I(004)/I(002) ratio for the graphitic materials obtained by heat treating at 3,000-3,250° C. is in the range from 0.2-0.5. In contrast, a graphitic film prepared from a NGP-PI film (90% NGP) with a HTT of 2,750° C. for 3 hours exhibits a I(004)/I(002) ratio of 0.78 and a Mosaic spread value of 0.21, indicating a practically perfect graphene single crystal with an exceptional degree of preferred orientation.

The “mosaic spread” value is obtained from the full width at half maximum of the (002) reflection in an X-ray diffraction intensity curve. This index for the degree of ordering characterizes the graphite or graphene crystal size (or grain size), amounts of grain boundaries and other defects, and the degree of preferred grain orientation. A nearly perfect single crystal of graphite is characterized by having a mosaic spread value of 0.2-0.4. Most of our NGP-PI derived materials have a mosaic spread value in this range of 0.2-0.4 (if obtained with a heat treatment temperature no less than 2,200° C.).

It may be noted that the I(004)/I(002) ratio for flexible graphite foil are typically <<0.05, practically non-existing in most cases. The I(004)/I(002) ratio for all NGP paper/membrane samples is <0.1 even after a heat treatment at 3,000° C. for 2 hours.

Scanning electron microscopy (SEM), transmission electron microscopy (TEM) pictures of lattice imaging of the graphene layer, as well as selected-area electron diffraction (SAD), bright field (BF), and dark-field (DF) images were also conducted to characterize the structure of various graphitic film materials.

We claim:

1. An elastic heat spreader film comprising:
A) A graphitic film prepared from graphitization of a polymer film or pitch film, wherein said graphitic film has graphitic crystals substantially parallel to one another and parallel to a film plane, having an inter-graphene spacing less than 0.34 nm in said graphitic crystals, and wherein said graphitic film has a thermal conductivity of at least 600 W/mK, an electrical conductivity no less than 4,000 S/cm, and a physical density greater than 1.5 g/cm³, all measured without the presence of a resin; and
B) an elastomer or rubber that permeates into said graphitic film from at least a surface of said graphitic film; wherein said elastomer or rubber is in an amount from 0.001% to 30% by weight based on the total heat spreader film weight;
wherein said elastic heat spreader film has a fully recoverable tensile elastic strain from 2% to 100% and an in-plane thermal conductivity from 100 W/mK to 1,750 W/mK.

2. The elastic heat spreader film of claim 1, wherein said elastomer or rubber contains a material selected from natural polyisoprene, synthetic polyisoprene, polybutadiene, chloroprene rubber, polychloroprene, butyl rubber, styrene-butadiene rubber, nitrile rubber, ethylene propylene rubber, ethylene propylene diene rubber, metallocene-based poly(ethylene-co-octene) elastomer, poly(ethylene-co-butene) elastomer, styrene-ethylene-butadiene-styrene elastomer, epichlorohydrin rubber, polyacrylic rubber, silicone rubber, fluorosilicone rubber, perfluoro-elastomers, polyether block amides, chlorosulfonated polyethylene, ethylene-vinyl acetate, thermoplastic elastomer, protein resilin, protein elastin, ethylene oxide-epichlorohydrin copolymer, polyurethane, urethane-urea copolymer, a sulfonated version thereof, or a combination thereof.

3. The elastic heat spreader film of claim 1, wherein said heat spreader film has a thickness from 10 nm to 500 μm.

4. The elastic heat spreader film of claim 1, wherein said graphitic film, when measured without said elastomer or rubber, has an inter-graphene spacing less than 0.337 nm, a thermal conductivity of at least 1,300 W/mK, an electrical conductivity no less than 8,000 S/cm, and a physical density greater than 1.8 g/cm³.

5. The elastic heat spreader film of claim 1, wherein said graphitic film, when measured without said elastomer or rubber, has an inter-graphene spacing less than 0.336 nm, a thermal conductivity of at least 1,500 W/mK, an electrical conductivity no less than 10,000 S/cm, and a physical density greater than 2.0 g/cm³.

6. The elastic heat spreader film of claim 1, wherein said elastic heat spreader film has a thickness t, a front surface, and a back surface, wherein said elastomer or rubber permeates from said front surface into said graphitic film by a distance of at least 1/10 t and/or permeates from said back surface into said film by a distance of at least 1/10 t and there is an elastomer-free zone inside said graphitic film.

7. The elastic heat spreader film of claim 1, wherein said elastic heat spreader film has a thickness t and an elastomer-free core size from 1/10 t to 9/10 t.

8. The elastic heat spreader film of claim 1, wherein said graphitic film exhibits an inter-graphene spacing less than 0.337 nm and a mosaic spread value less than 1.0.

9. The elastic heat spreader film of claim 1, wherein said graphitic film exhibits a degree of graphitization no less than 60% and/or a mosaic spread value less than 0.7.

10. The elastic heat spreader film of claim 1, wherein said graphitic film exhibits a degree of graphitization no less than 90% and/or a mosaic spread value less than 0.4.

11. The elastic heat spreader film of claim 1, having a thermal conductivity no less than 500 W/mK, and/or an electrical conductivity no less than 5,000 S/cm, all measured along a thin film plane direction.

12. The elastic heat spreader film of claim 1, having a thermal conductivity no less than 800 W/mK, and/or an electrical conductivity no less than 8,000 S/cm, all measured along a thin film plane direction.

13. The elastic heat spreader film of claim 1, having a thermal conductivity no less than 1,200 W/mK, and/or an electrical conductivity no less than 12,000 S/cm, all measured along a thin film plane direction.

14. The elastic heat spreader film of claim 1, having a thermal conductivity no less than 1,500 W/mK, and/or an electrical conductivity no less than 20,000 S/cm, all measured along a thin film plane direction.

15. An electronic device containing the elastic heat spreader film of claim 1, as a thermal management element.

16. A structural member containing the elastic heat spreader film of claim 1, as a load-bearing and thermal management element.

17. A process for producing the elastic heat spreader film of claim 1, said process comprising:
a) Providing at least one film of polymer or pitch, having a film thickness from 10 nm to 1 mm;
b) subjecting said at least one film to heat treatment at a graphitization temperature greater than 2000° C. in an non-oxidizing atmosphere to graphitize the film for obtaining a porous graphitized film, having a front surface and a back surface;
c) impregnating a rubber or elastomer resin from at least one of the front and back surfaces into said porous graphitized film to obtain a rubber/elastomer-impregnated film; and
d) compressing and consolidating said rubber/elastomer-impregnated film to produce said elastic heat spreader film.

18. The process of claim 17, wherein said polymer film is selected from the group consisting of polyimide, polyamide, phenolic resin, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, poly(pyromellitimide), poly(p-phenylene-isophthalamide), poly(m-phenylene-zoimidazole), poly(phenylene-benzobisimidazole), polyacrylonitrile, and combinations thereof.

19. The process of claim 17, wherein said non-oxidizing atmosphere includes hydrogen gas, nitrogen gas, an inert gas, or a combination thereof.

20. The process of claim 17, wherein said pitch film is selected from a film of petroleum pitch, coal tar pitch, a polynuclear hydrocarbon, or a combination thereof.

21. The process of claim 20, wherein said polynuclear hydrocarbon is selected from naphthalene, anthracene, phenanthrene, tetracene, chrysene, triphenylene, pyrene, pentacene, benzo-pyrene, corannulene, benzo-perylene, coronene, ovalene, benzo-fluorene, a derivative thereof having a substituent on a ring structure thereof, a chemical derivative thereof, or a combination thereof.

22. The process of claim 17, wherein said film of polymer or pitch further comprises from 0.01% to 50% by weight of multiple graphene sheets dispersed therein and wherein said graphene sheets are selected from pristine graphene, oxidized graphene, reduced graphene oxide, fluorinated graphene, hydrogenated graphene, doped graphene, chemically functionalized graphene, or a combination thereof.

23. The process of claim 17, wherein said film of polymer or pitch further comprises from 0.01% to 50% by weight of expanded graphite flakes or exfoliated graphite.

24. The process of claim 17, wherein said process further comprises, prior to step (b), a procedure of carbonizing said film at a temperature selected from 200 to 2,500° C., and wherein the graphitization temperature is from 2,500° C. to 3,250° C.

25. The process of claim 17, wherein said elastomer or rubber contains a material selected from natural polyisoprene, synthetic polyisoprene, polybutadiene, chloroprene rubber, polychloroprene, butyl rubber, styrene-butadiene rubber, nitrile rubber, ethylene propylene rubber, ethylene propylene diene rubber, metallocene-based poly(ethylene-co-octene) elastomer, poly(ethylene-co-butene) elastomer, styrene-ethylene-butadiene-styrene elastomer, epichlorohydrin rubber, polyacrylic rubber, silicone rubber, fluorosilicone rubber, perfluoro-elastomers, polyether block amides, chlorosulfonated polyethylene, ethylene-vinyl acetate, thermoplastic elastomer, protein resilin, protein elastin, ethylene oxide-epichlorohydrin copolymer, polyurethane, urethane-urea copolymer, a sulfonated version thereof, or a combination thereof.

26. The process of claim 17, wherein said porous graphitized film has a physical density from 0.01 g/cm³ to 1.5 g/cm³ and, upon compressing and consolidating, said rubber/elastomer-impregnated film has a physical density from 1.5 g/cm³ to 2.25 g/cm³.

27. The process of claim 17, wherein said graphitization temperature is from 2,500° C. to 3,250° C.

28. The process of claim 17, wherein said process is a continuous process that includes continuously or intermittently feeding said polymer or pitch film into a carbonization zone containing a temperature from 300° C. to 2,500° C. and then into a graphitization zone containing a temperature from 2,500° C. to 3,250° C., followed by retreating said porous graphitized film from said graphitization zone.

29. The process of claim 17, wherein said polymer or pitch film is under a compression stress while being graphitized.

30. The process of claim 17, wherein said polymer or pitch film is supported on a first refractory material plate and covered by a second refractory material plate to exert a compressive stress to said polymer or pitch film while being graphitized.

31. The process of claim 30, wherein said first refractory material or second refractory material is selected from graphite, a refractory metal, or a carbide, oxide, boride, or nitride of a refractory element selected from tungsten, zirconium, tantalum, niobium, molybdenum, tantalum, or rhenium.

32. The process of claim 17, wherein said polymer or pitch film has a thickness from 1 μm to 200 μm.
